(19) United States
(12) Patent Application Publication
(10) Pub. No.: US 2026/0005075 A1
(43) Pub. Date: Jan. 1, 2026

(54) LATERAL MEASUREMENTS FOR DETECTING DELAMINATION OR WEAR IN A SEMICONDUCTOR DEVICE

(71) Applicant: Infineon Technologies AG, Neubiberg (DE)

(72) Inventors: Thomas Blasius, Haar (DE); Andre Mourrier, Manosque (FR); Alberto Zanardi, Villach (AT)

(21) Appl. No.: 18/761,062

(22) Filed: Jul. 1, 2024

(51) Int. Cl. H01L 21/66; H01L 27/02

(52) U.S. Cl. CPC H01L 22/34; H01L 22/12; H10D 89/10

(57) ABSTRACT

A circuit device may be configured to perform early detection of degradation problems associated with delamination or cratering in the device. The device may comprise a semiconductor layer comprising at least a portion of one or more power transistors, a metallization layer formed over the semiconductor layer, and a plurality of excitation elements formed into the semiconductor layer, wherein the excitation elements extend through the semiconductor layer to the metallization layer such that an excitation pulse can be delivered into a first excitation element and received from a second excitation element after passing laterally through the metallization layer.

### TECHNICAL FIELD

This disclosure relates to semiconductor devices such as semiconductor-based power switches.

### BACKGROUND

Semiconductor-based power switches (e.g., power transistors) are typically formed in a semiconductor material. A metallization layer is formed over the semiconductor material, e.g., via a metal spattering deposition process. Delamination of the metallization layer is undesirable and may affect or degrade the performance of semiconductor-based power switches. Delamination is a degradation effect (i.e., wear) that typically occurs slowly over the lifetime use of the power switch due to operation under repetitive high stress conditions, such as conditions outside the limits of specification of the power switch or conditions outside the mission profile of the power switch. Cratering is another degradation affect that can occur over the lifetime of semiconductor-based power switches due to repetitive high stress conditions. Cratering may occur in power switches that conduct current in vertical channels downward through the semiconductor device. These or other degradations in power switches are sometimes attributed to aging of the power switches.

In general, it is desirable to detect semiconductor delamination issues, cratering issues, or other types of problems or wear, prior to actual device failure. Tracking or predicting power switch degradation or failure before the degradation or failure occurs may be especially desirable in vehicles, or any other systems where user safety is important.

### SUMMARY

A circuit device, e.g., one or more power transistors, may be configured to perform early detection of aging problems associated with delamination or cratering in the device. The circuit device may comprise a semiconductor layer comprising at least a portion of one or more power transistors, a metallization layer formed over the semiconductor layer, and a plurality of excitation elements formed into the semiconductor layer, wherein the excitation elements extend through the semiconductor layer to the metallization layer such that an excitation pulse can be delivered into a first excitation element and received from a second excitation element after passing laterally through the metallization layer. In some examples, a pulse detector circuit and a pulse receiver circuit are formed in the semiconductor layer, allowing the device to perform self-checks for degradation problems that may exist.

In some examples, this disclosure describes a device, e.g., a circuit device. The device may comprise a semiconductor layer comprising at least a portion of one or more power transistors, a metallization layer formed over the semiconductor layer, and a plurality of excitation elements formed into the semiconductor layer. The excitation elements extend through the semiconductor layer to the metallization layer such that an excitation pulse can be delivered into a first excitation element and received from a second excitation element after passing laterally through the metallization layer.

In some examples, this disclosure describes a system that comprises a circuit device and a controller configured to control the circuit device. The circuit device may comprise a semiconductor layer comprising at least a portion of one or more power transistors, a metallization layer formed over the semiconductor layer, and a plurality of excitation elements formed into the semiconductor layer, wherein the excitation elements extend through the semiconductor layer to the metallization layer such that an excitation pulse can be delivered into a first excitation element and received from a second excitation element after passing laterally through the metallization layer. The controller may be configured to receive an alert from the circuit device based on the excitation pulse.

In some examples, this disclosure describes a method that comprises injecting a signal in a circuit device, wherein the circuit device comprises: a semiconductor layer comprising at least a portion of one or more power transistors; a metallization layer formed over the semiconductor layer; and a plurality of excitation elements formed into the semiconductor layer, wherein the excitation elements extend through the semiconductor layer to the metallization layer, wherein injecting the signal occurs into a first excitation element. The method may also comprise receiving the signal via a second excitation element after the signal passes upward through the semiconductor layer on the first excitation element, laterally through the metallization layer, and downward through the semiconductor layer on the second excitation element; and detecting whether a degradation problem exists in the circuit device based on the received signal.

Details of these and other examples are set forth in the accompanying drawings and the description below. Other features, objects, and advantages will be apparent from the description and drawings, and from the claims.

### BRIEF DESCRIPTION OF THE DRAWINGS

FIGS. 1A-1C are cross-sectional conceptual views of a device configured to allow for lateral measurements though a metallization layer that is formed on a semiconductor layer.

FIGS. 2A-2D are another set of cross-sectional conceptual views of a device configured to allow for lateral measurements though a metallization layer that is formed on a semiconductor layer.

FIG. 3 is a cross-sectional conceptual view of a device configured to allow for lateral measurements though a metallization layer that is formed on a semiconductor layer.

FIG. 4 is a perspective conceptual view of a device configured to allow for lateral measurements though a metallization layer that is formed on a semiconductor layer.

FIG. 5 is a block diagram showing an example device of this disclosure within a larger system.

FIG. 6 is conceptual view of a device configured to allow for lateral measurements though a metallization layer that is formed on a semiconductor layer.

FIGS. 7A and 7B are conceptual views of a device configured to allow for two different lateral measurements though a metallization layer that is formed on a semiconductor layer.

FIG. 8 is another cross-sectional conceptual view of a device configured to allow for lateral measurements though a metallization layer that is formed on a semiconductor layer.

FIG. 9 is a flow diagram showing measurements at different times consistent with this disclosure, and additional fleet-level analysis that may be performed.

FIG. 10 is a set of graphs corresponding to stages shown in FIG. 9.

FIG. 11 is an example flow diagram consistent with one or more techniques of this disclosure.

### DETAILED DESCRIPTION

Semiconductor-based power switches (e.g., power transistors) are circuit devices formed in a semiconductor material and commonly used to control the delivery of electric power to a load. These devices often include a metallization layer is formed over the semiconductor material. The semiconductor material may include different doped layers, and a transistor structure is formed by the arrangement of the different doped layers and the metallization layer. In some cases, current may flow horizontally through the device, and in some cases, current may flow vertically through the device. The direction of current flow may depend on the type of power transistor(s) that is formed in the device and the arrangement of layers used to form the power transistor(s).

Degradation of the metallization layer can occur over time, e.g., due to repetitive high stress conditions and/or operation outside the specification or the mission profile of the power transistor(s) formed in the device. For example, when current flows continuously, extreme and repetitive temperature changes may occur, possibly causing cratering artifacts to be formed in the metallization layer. Delamination is another degradation effect that may occur in semiconductor-based power switch devices under similar harsh conditions or short circuit operation. Early detection of these degradation effects is difficult but desirable. For example, if degradation effects can be detected before device failure, predictive maintenance can be performed, e.g., prompting replacement of one or more devices or circuit boards prior to device failure. Predictive maintenance of circuit devices, for example, is highly desirable in vehicular systems, in order to improve safety.

This disclosure recognizes that degradation effects associated with the metallization layer of a semiconductor-based power switch can be better identified by creating a signal measurement path that travels laterally through the metallization layer. An excitation pulse can be delivered from the semiconductor layer and upward through the semiconductor layer. The excitation pulse may then pass laterally through the metallization layer and downward back through the semiconductor layer, and the excitation pulse can then be detected at a different location in semiconductor layer relative to where it was generated. Signal changes to the excitation pulse, which passes laterally through the metallization layer, may occur due to degradation effects in the metallization layer. Therefore, by comparing the received signal to one or more thresholds, device degradation may be identified and failure may be predicted before the failure occurs. In some cases, predictive maintenance on the system may be performed (e.g., prompting device or circuit board replacement) prior to such device failure.

In some examples, one or more pulse injector circuits and one or more pulse receiver circuits may be formed in the semiconductor layer, thereby creating a self-check feature for the power transistors of the device whereby the device itself includes the ability to deliver and receive pulses that are configured to pass or propagate laterally through the metallization layer for.

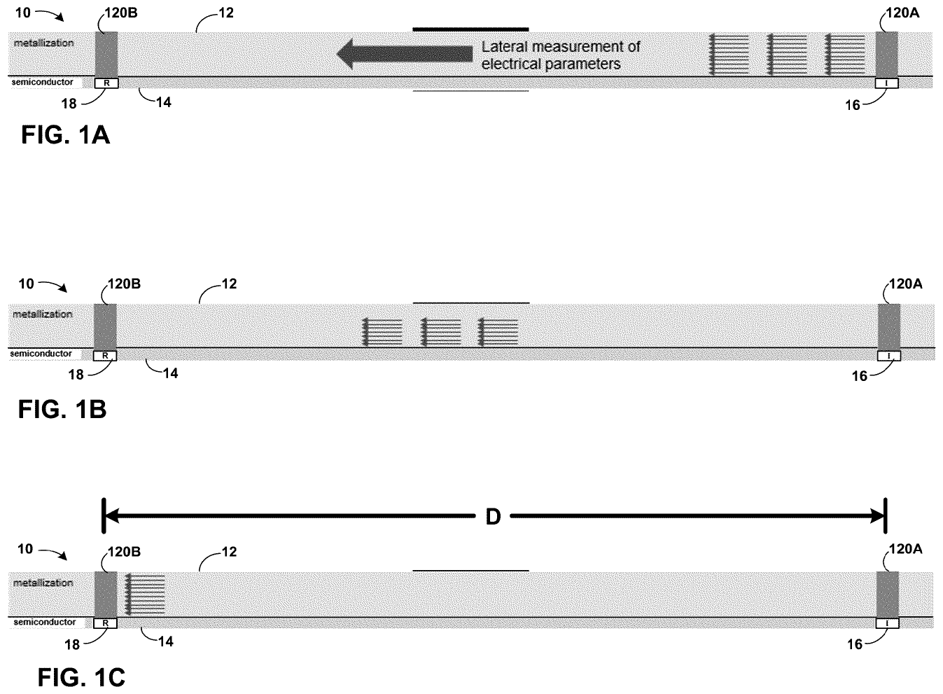

FIGS. 1A-1C are cross-sectional conceptual views of a device 10 configured to allow for lateral measurements though a metallization layer 12 that is formed on a semiconductor layer 14. Semiconductor layer 14 may comprise at least a portion of one or more power transistors. Semiconductor layer 14 may comprise a plurality of different layers, such as P-doped layers and N-doped layers. Metallization layer 12 is formed over the semiconductor layer 14, e.g., via a metal spattering process or another type of process. In some examples, a transistor structure is formed by semiconductor layer 14 and metallization layer 12, and the arrangement and shape of the different layers of semiconductor layer 14 along with the arrangement and shape of metallization layer 12 may define different structures of the power transistor(s), e.g., the source, the drain, the body, and the gate, in the example of a metal oxide semiconductor field effect transistor (MOSFET). In some examples, semiconductor layer 14 may be formed on a semiconductor substrate, which is not shown in FIGS. 1A-1C.

According to this disclosure, device 10 includes a plurality of excitation elements 120A, 120B formed into semiconductor layer 14. Excitation elements 120A, 120B extend through the semiconductor layer 14 to the metallization layer 12 such that an excitation pulse can be delivered into a first excitation element 120A and received from a second excitation element 120B after passing laterally through the metallization layer 12, as shown in FIGS. 1A and 1B by the lateral arrows and as labeled in FIG. 1 annotation “lateral measurement of electrical parameters.”

Consistent with FIGS. 1A-1C, the plurality of excitation elements 120A, 120B are arranged linearly along a major diameter of the device. Excitation elements 120A, 120B, in the most general sense, may refer to any signal transfer medium. This disclosure generally discussed electrical signals, but it may also be plausible to use other types of signals, such as ultrasound signals. In the example of electrical pulses, excitation elements 120A, 120B may comprise conductors.

In some examples, excitation elements 120A, 120B comprise conductor elements that extend through semiconductor layer 14 to metallization layer 12 such that an electrical current pulse can be delivered into the first excitation element 120A and received from the second excitation element 120B after passing upward on the first excitation element 120A and through semiconductor layer 14, laterally through the metallization layer 12, and downward on the second excitation element 120B and into the semiconductor layer 14.

Moreover, in some examples, device 12 further comprises a pulse injector 16 (labeled “I” for injector). Pulse injector 16 may be formed in the semiconductor layer 14 and configured to generate the excitation pulse and deliver the excitation pulse to first excitation element 120A and laterally through the metallization layer 12. In addition, device 10 may comprise a pulse receiver 18 (labeled “R” for receiver). Pulse receiver 18 may also be formed in semiconductor layer 14 and configured to receive the excitation pulse at the second excitation element 120B after the pulse passes upward on the first excitation element 120A and through semiconductor layer 14, laterally through the metallization layer 12, and downward on the second excitation element 120B and back through semiconductor layer 14.

First excitation element 120A may be formed to be a distance “D” from second excitation element 120B. The desired or optimal distance D may depend on the transistor structure that is being monitored. In general, the distance D may be greater than 20 micrometers, and may be in a range of 20 to 500 micrometers.

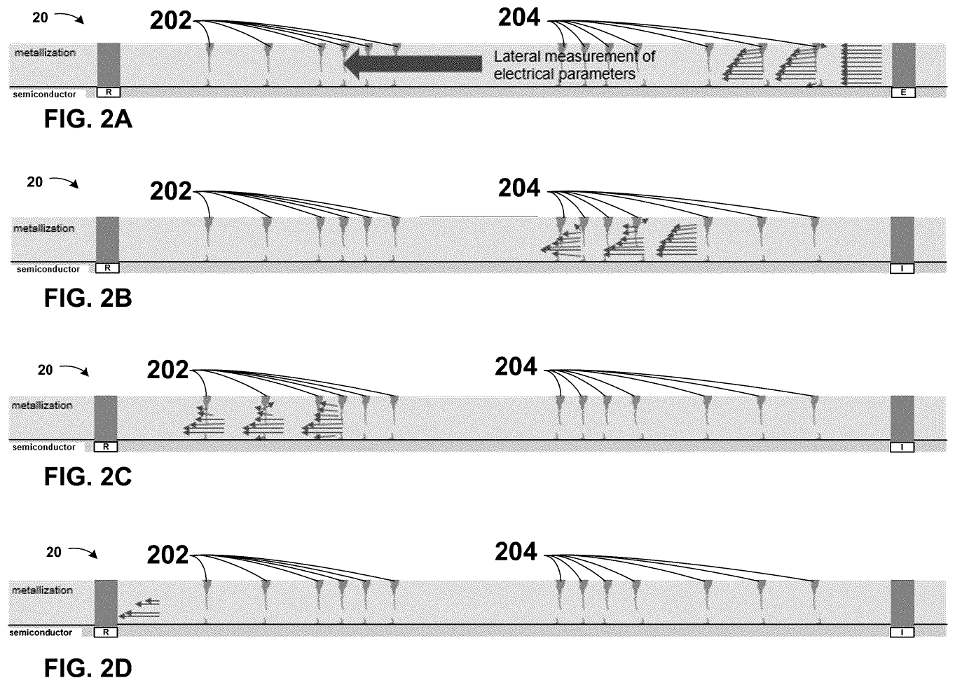

FIGS. 2A-2D are cross-sectional conceptual views of a device 20 configured to allow for lateral measurements though a laminated metallization layer 22 that is formed on a semiconductor layer 24. In some examples, device 20 may correspond to device 10 of FIGS. 1A-1C. As illustrated in FIGS. 2A-2D, cratering features 202, 204 may form in device 20 over time. For example, cratering features 202, 204 may comprise metallization inhomogeneities formed in the transistor structure within device 20. Again, cratering features 202, 204 are generally undesirable, and caused by degradation of the metallization layer. Lateral measurement of electrical parameters of the metallization layer (e.g., shown by the lateral arrows) may be especially useful in detecting wear and potential problems associated with tunneling features 202, 204. The various defections of lateral arrows shown in FIGS. 2A-2D, for example, may represent signal loss due to scattering at the metallization inhomogeneities, and therefore, by sending a controlled pulse laterally through the metallization layer of device 20 and detecting the pulse, the detected pulse may be useful in identifying wear (e.g., associated with cratering features 202, 204), and may even be useful to preempt or predict failure of device 20 in the future.

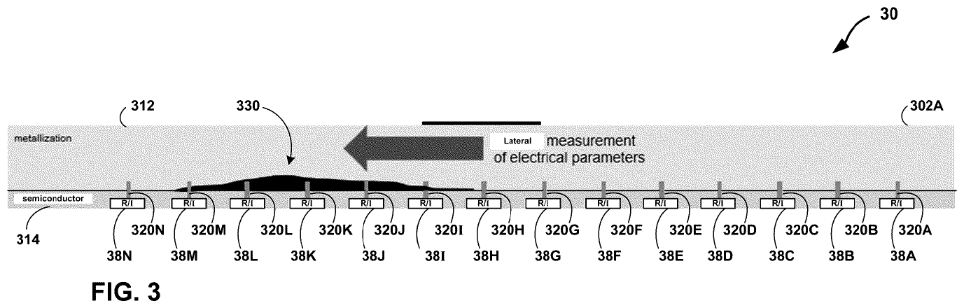

FIG. 3 is a cross-sectional conceptual view of a device 30 configured to allow for lateral measurements though a metallization layer 312 that is formed on a semiconductor layer 314. Device 30 of FIG. 3 can be viewed as being a different example than device 10 FIG. 1, or device 30 FIG. 3 can also be viewed as a larger depiction of device 10. Whereas device 10 shows two excitation elements 120A, 120B, device 30 includes a much larger plurality of excitation elements 320A-320N. In this case, the plurality of excitation elements 320A-320N are arranged such that each of the excitation elements 320A-320N is equally spaced relative to another of the excitation elements 320A-320N. For example, the distance between excitation element 320A and 320B may be the same as the distance between element 320B and 320C. Similarly, the distance between excitation element 320A and 320B may be the same as the distance between element 320B and 320C, and the distance between excitation element 320C and 320D may be the same as the distance between element 320D and 320E. In some examples, any two adjacent excitation elements may have a similar distance from one another as any other two adjacent excitation elements. Different lateral signals passing through different lateral paths of metallization layer 312 can be used to identify wear in device 30, and possibly to identify or pinpoint the location of problem 330 within device. Problem 330, for example, may comprise delamination wear associated with metallization layer 312.

Specific measurements between excitation elements 320I and 320J, between excitation elements 320J and 320H, between excitation elements 320H and 320K, between excitation 320K and 320L, and between excitation elements 320L and 320M, for example, may allow for identification of problem 330 and possibility the location of problem 330, e.g. to help detect spread or growth of problem 330 over time. In response to detecting problem 330, device 30 may be disabled or specific current channels associated with problem 330 may be disabled, while still allowing some current delivery via other channels. Partial disabling of device 30, for example, may correspond to a so-called “LIMP HOME” operation in a motor vehicle, e.g., in which case device may operate in a low-current delivery mode in which the device has one or more partially disabled current channels. In some examples, device 30 may be placed in a low current or limited power mode of operation. In some examples, device 30 may be flagged for replacement or a larger circuit board associated with device 30 may be flagged for replacement, in response to identification of problem 330. As described in greater detail below, problem 330 or undesirable cratering features 202, 204 may be identified by comparing received pulses to one or more thresholds.

Device 30 includes a plurality of receiver/injector circuits 38A-38N corresponding to each of excitation elements 320A-320M. Each of the receiver/injector circuits 38A-38N may be configured as a pulse receiver or a pulse injector. Therefore, pulses can be generated and received across any two adjacent ones of receiver/injector circuits 38A-38N for self-checking the integrity of device 30, i.e., specifically at different structural locations across different adjacent ones of excitation elements 320A-320M.

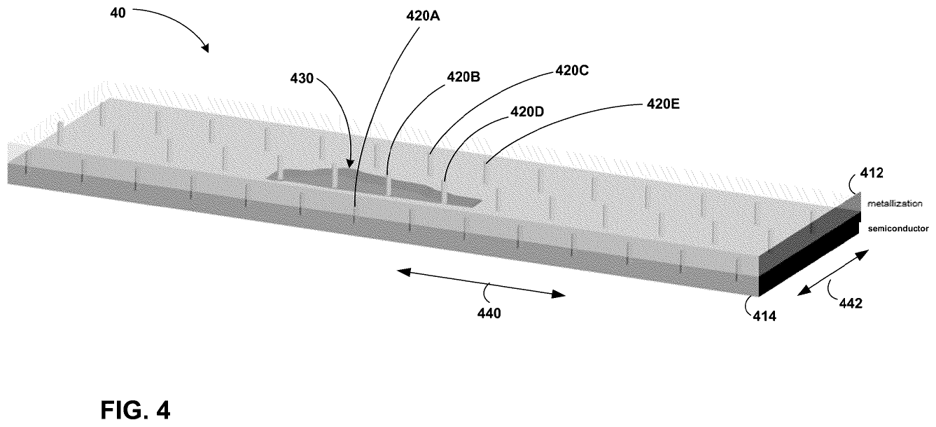

FIG. 4 is a cross-sectional conceptual view of a device 40 configured to allow for lateral measurements though a metallization layer 412 that is formed on a semiconductor layer 414. Device 40 of FIG. 4 can be viewed as being a more specific example of device 30 of FIG. 3. In this case, the plurality of excitation elements is arranged in a two-dimensional matrix in device 40. Problem 430 illustrated in FIG. 4 may be similar to problem 330 illustrated in FIG. 3, e.g., a delamination problem.

In FIG. 4 only some of the plurality of excitation elements are labeled (e.g., 420A-420E). By arrangement in a two-dimensional matrix, lateral measurements can be made in two different dimensions (e.g., an X axis 440 and a Y axis 442). For example, a signal pulse between excitation element 420A and excitation element 420B can measure pulse scattering at inhomogeneities (or other electrical charactorisitcs) of metallization layer 412 along the Y axis 442. Similarly, a signal pulse between excitation element 420B and excitation element 420C can measure pulse scattering at inhomogeneities (or other electrical charactorisitcs) of metallization layer 412 along the Y axis 442 at a different location within device 40 than the measurement between excitation element 420A and excitation element 420B.

In contrast to the Y axis 442, a signal pulse between excitation element 420B and excitation element 420D can measure pulse scattering at inhomogeneities (or other electrical charactorisitcs) of metallization layer 412 along the X axis 440. Similarly, a signal pulse between excitation element 420C and excitation element 420E can measure pulse scattering at inhomogeneities (or other electrical charactorisitcs) of metallization layer 412 along the X axis 440 at a different location within device 40 than the measurement between excitation element 420B and excitation element 420D.

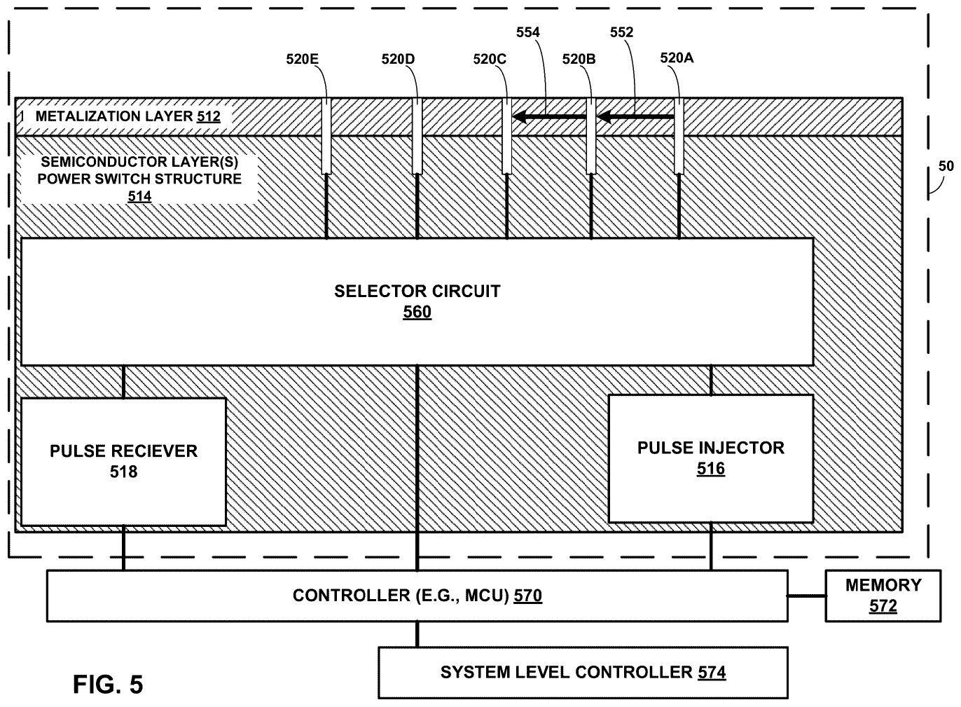

FIG. 5 is a block diagram showing an example device 50 of this disclosure within a larger system. Device 50 may generally correspond to an example of device 10. For example, device 50 may comprise a semiconductor layer 514 comprising at least a portion of one or more power transistors (e.g., a power switch structure). A metallization layer 512 is formed over semiconductor layer 514. A plurality of excitation elements 520A-520E are formed into the semiconductor layer, wherein the excitation elements 520A-520E extend through the semiconductor layer 514 to the metallization layer 512 such that an excitation pulse can be delivered into a first excitation element (e.g., 520A) and received from a second excitation element (e.g., 520B) after passing laterally 552 through the metallization layer.

Device 50 of FIG. 5 is different than device 30 of FIG. 3. For example, whereas device 30 includes receiver/injector circuits 38A-38N that corresponds to each excitation of the excitation elements 320A-320N, device 50 includes a pulse injector circuit 516 and a pulse receiver circuit 518 along with a selector circuit 560. Selector circuit 560 may comprise switches, or a multiplexer, or another type of selector circuit. Selector circuit 560 may be configured to select the first excitation element 520A for the pulse injector 516 and select the second excitation element 520B for the pulse receiver 518 in a first instance of time, e.g., for measuring laterally 552 through the metallization layer 512. Then, at a second instance of time, the selector circuit 560 may be configured to select the second excitation element 520B for the pulse injector 516 and select a third excitation element 520C for the pulse receiver 518, e.g., for measuring laterally 554 (at a different location than laterally 552) through the metallization layer 512.

As shown in FIG. 5 (and also consistent with the other examples), a controller 570 may be configured to control operation of pulse reliever 518 and pulse injector 516. Controller 570 may be configured to receive the measured pulses. Controller 570 may comprise a compare circuit that is configured to compare measured pulses with one or more thresholds in order to determine if any problems may exist in metallization layer. In the example of vehicle components, controller 570 for example may comprises a so-called automotive microcontroller unit (MCU), controller 570 may be connected to a memory 572 and a system level controller 574. Memory 572 can be used to log measurement results over time, e.g., to help track the degradation of metallization layer 512. System level controller 574 may periodically connect to an even larger system to allow for fleet-level analysis of the measured data in the vehicle associated with device 50 and other similar devices in other vehicles. In some examples, controller 570 may also be formed in semiconductor layer 514.

FIG. 5 illustrates one example of a system that comprises device 50 in the form of a circuit device that includes a semiconductor layer 514 comprising at least a portion of one or more power transistors, and a metallization layer 512 formed over the semiconductor layer. A plurality of excitation elements 520A-520E are formed into the semiconductor layer 514, wherein the excitation elements 520A-520E extend through the semiconductor 514 layer to the metallization layer 512 such that an excitation pulse can be delivered into a first excitation element (e.g., 520A) and received from a second excitation element (e.g., 520B) after passing laterally 552 through the metallization layer 512. The system also includes a controller 570 configured to control device 50, wherein the controller receives an alert from the circuit device based on the excitation pulse. Controller 570 may be formed in semiconductor layer 514 in some examples, and controller 570 may be external to device 50 (as illustrated in FIG. 5) in other examples. Controller 570 may comprise a compare unit configured to compare the received excitation pulse to a threshold. The threshold may be pre-stored in memory 572 or the threshold may be defined by the pulse injector 516 based on the generated pulse.

In some examples, controller 570 may be configured to issue an alert (e.g., to system level controller 574) in response to output of a compare unit indicating a potential problem with the device. The alert may indicate a potential delamination or cratering problem with the device 50. In some examples, device 50 may be at least partially disabled by controller 570 in response to the alert. In some examples, device 50 may be operated in a current limited or power limited mode in response to the alert. In some examples, the alert identifies a need to replace device 50 or a need to replace a larger component or module that includes device 50, e.g., within a vehicle.

Pulse injector 516 may be configured to generate the excitation pulse and deliver the excitation pulse to a first excitation element (e.g., 520A). Pulse receiver 518 may be configured to receive the excitation pulse at a second excitation element (e.g., 520B). A selector circuit 560 may switches, wherein selector circuit 560 is configured to select the first excitation element 520A for the pulse injector 516 and select the second excitation element 520B for the pulse receiver 518 in a first instance of time. Again, a compare unit within controller 570 may be configured to compare the received excitation pulse to a threshold and issue the alert in response to the received excitation indicating a potential problem with device 50. Controller 570 may be formed within semiconductor layer 514, in some examples, in which case, device 50 issues the alert directly to system level controller 574. In some examples, controller 570 may be further configured to store comparison results of a compare unit over a history associated with device 50. Moreover, in some examples, controller 570 may be configured to output the comparison results for fleet-level analysis of device 50 relative to other devices in a fleet (e.g., other devices within other vehicles of a fleet of vehicles). In this way, a fleet-level (e.g., statistical) analysis may be performed to better determine or identify the health of device 50 based on the health and/or the historical lifetime health of similar devices used within a fleet of vehicles.

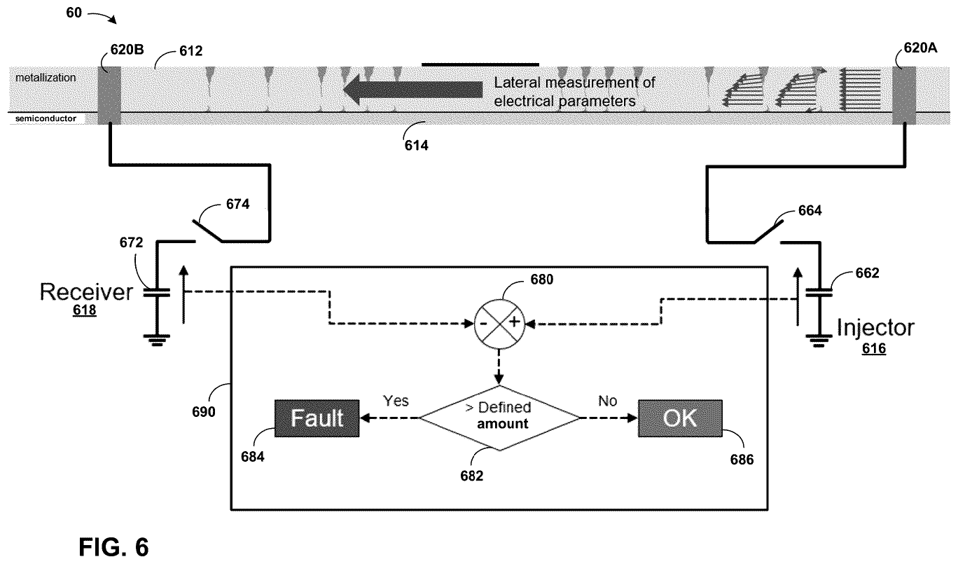

FIG. 6 is conceptual view of a device 60 configured to allow for lateral measurements though a metallization layer 612 that is formed on a semiconductor layer 614. Device 60 of FIG. 6 is one example of device 10 of FIG. 1. Device 60 includes a plurality of excitation elements 620A, 620B formed into semiconductor layer 614. Excitation elements 620A, 620B extend through the semiconductor layer 614 to the metallization layer 612 such that an excitation pulse can be delivered into a first excitation element 620A and received from a second excitation element 620B after passing laterally through the metallization layer 612, as shown by the lateral arrows shown in FIG. 6.

Consistent with FIG. 6, the plurality of excitation elements 620A, 620B are arranged linearly along a major diameter of device 60. With the example of electrical signals, excitation elements 620A, 620B comprise conductor elements that extend through semiconductor layer 614 to metallization layer 612 such that an electrical current pulse can be delivered into the first excitation element 620A and received from the second excitation element 620B after passing upward on the first excitation element 620A and through semiconductor layer 614, laterally through the metallization layer 612, and downward on the second excitation element 620B and into the semiconductor layer 614.

Conceptually illustrated in FIG. 6 is a pulse injector 616 and a pulse receiver 618. Injector 616 and receiver 618 may each be formed in semiconductor layer 614. Pulse injector 616 may be formed in the semiconductor layer 614 and configured to generate the excitation pulse and deliver the excitation pulse to first excitation element 620A and laterally through the metallization layer 612. In this example, pulse injector 616 may comprise a capacitor 662 that is charged with the pulse, and a switch 664 that is controlled to discharge the pulse on capacitor 662 into excitation element 620A.

Pulse receiver 618 may also be formed in semiconductor layer 614 and configured to receive the excitation pulse at the second excitation element 620B after the pulse passes upward on the first excitation element 620A and through semiconductor layer 614, laterally through the metallization layer 612, and downward on the second excitation element 620B and back through semiconductor layer 614. Pulse receiver 618 may comprise a similar structure as pulse injector 616 but operates in a reciprocal manner relative to pulse injector 616. Switch 674 is controlled so that the energy pulse can be collected on capacitor 672. Thus, the pulse is energized on capacitor 662 the injector side, discharged such that it passes laterally through metallization layer 612 and then collected on capacitor 672 on the receiver side. A controller may operate switches 674 664 in a synchronous manner to send and receive the pulse from injector 616 to receiver 618.

Element 690 represents logic circuitry. The controller that implements logic element 690 may be formed in semiconductor layer 614 or may be an external MCU or other type of external controller relative to device 60. In either case, logic element 690 compares the received pulse to a threshold, e.g., via compare unit 680. In some examples, compare unit 680 is formed in semiconductor layer 614 and in some examples, compare unit 680 is external to semiconductor layer 614 and part of an external MCU. The threshold may be defined by the sending pulse, or the threshold may be pre-defined and stored on the receiver side based on a known pulse that is being generated on the injector side. If the received pulse deviates from the threshold by some defined amount 682 (i.e., a threshold of deviation between the sending pulse and the receiving pulse), then logic element 690 may issue a fault 684. However, if the sending pulse and the receiving pulse are sufficiently similar (i.e., if the receiving pulse does not deviate from the threshold by a defined amount), then logic element 690 may output signal indicating that device 610 is OK 686. In some examples, the determination of whether the received pulse deviates from the threshold by some defined amount 682 may be performed by an MCU.

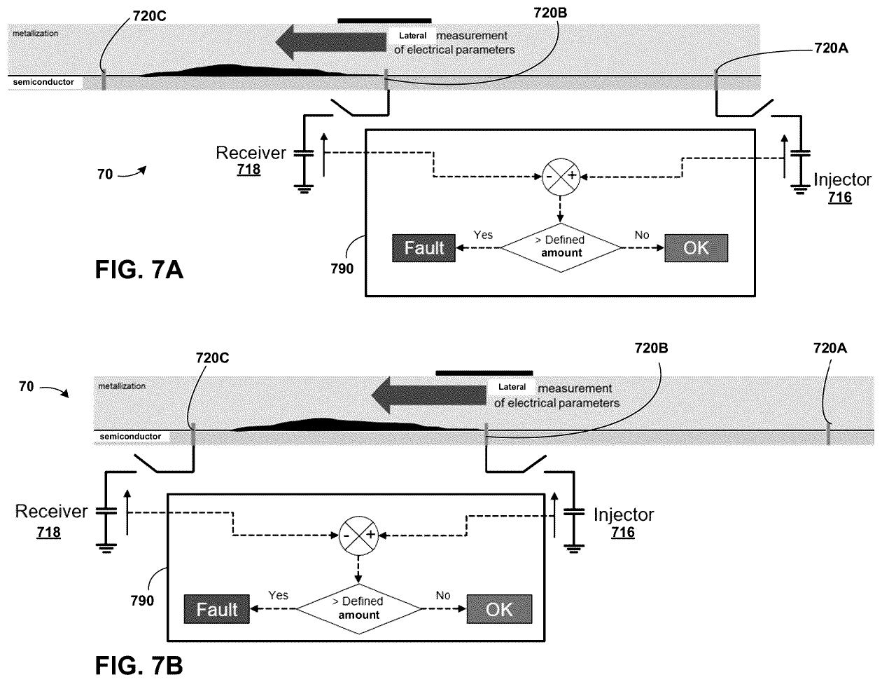

FIGS. 7A and 7B are conceptual views of a device 70 configured to allow for two different lateral measurements though a metallization layer that is formed on a semiconductor layer. Device 70 and the depiction in FIGS. 7A and 7B is very similar to device 60 and the depiction in in FIG. 6, in many respects. Device 60 is similar to device 70, and injector 716 and receiver 718 operate similarly to injector 616 and receiver 618 of FIG. 6.

FIGS. 7A and 7B demonstrate how two different lateral measurements though a metallization layer can be made, and in this case, the same excitation element used on the receive side in FIG. 7A can be used on the injector side in FIG. 7B. In some examples consistent with FIGS. 7A and 7B, the same structure may be used as the injector for FIG. 7A and then used as the receiver for FIG. 7B (e.g., consistent with the example shown in FIG. 3). Alternatively, an injector and a receiver could be used with a selector circuit to achieve different sending and receiving locations through device 70 (e.g., consistent with the example shown in FIG. 5).

In FIG. 7A excitation element 720A is paired with injector 716 and excitation element 720B is paired with receiver 718, e.g., in a first instance of time. Then, in a second instance of time (i.e., after the first instance of time), excitation element 720B is paired with injector 716 and excitation element 720C is paired with receiver 718. Again, in some examples, an injector and a receiver could be used with a selector circuit to achieve different sending and receiving locations through device 70 (e.g., consistent with the example shown in FIG. 5), while in other examples, the same structure may be used as the injector for FIG. 7A and then used as the receiver for FIG. 7B (e.g., consistent with the example shown in FIG. 3).

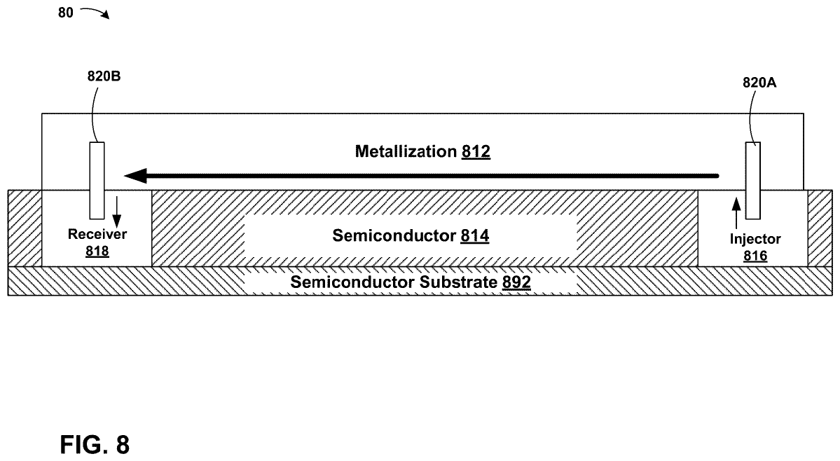

FIG. 8 is another cross-sectional conceptual view of a device configured to allow for lateral measurements though a metallization layer that is formed on a semiconductor layer. In some examples, device 80 of FIG. 8 may correspond to device 10 of FIG. 1. In the example shown in FIG. 8, device 80 comprises a semiconductor layer 814 formed over a semiconductor substrate 892. A metallization layer 812 is formed over semiconductor layer 814.

Device 80 includes a plurality of excitation elements 820A, 820B formed into semiconductor layer 814. Excitation elements 820A, 820B extend through the semiconductor layer 818 to the metallization layer 814 such that an excitation pulse can be delivered into a first excitation element 812A and received from a second excitation element 812B after passing laterally through the metallization layer 812.

The plurality of excitation elements 820A, 820B are arranged linearly along a major diameter of the device. Again, excitation elements 820A, 820B, in the most general sense, may refer to any signal transfer medium. This disclosure generally discussed electrical signals, but it may also be plausible to use other types of signals sensitive to scattering at cratering or delamination inhomogeneities, such as ultrasound signals. In the example of electrical pulses, excitation elements 820A, 820B may comprise conductors.

In some examples, excitation elements 820A, 820B comprise conductor elements that extend through semiconductor layer 814 to metallization layer 812 such that an electrical current pulse can be delivered into the first excitation element 820A and received from the second excitation element 820B after passing upward on the first excitation element 820A and through semiconductor layer 814, laterally through the metallization layer 812, and downward on the second excitation element 820B and into the semiconductor layer 814.

Device 812 further comprises a pulse injector 816. Pulse injector 816 may be formed in the semiconductor layer 816 and configured to generate the excitation pulse and deliver the excitation pulse to first excitation element 820A and laterally through the metallization layer 812. In addition, device 80 may comprise a pulse receiver 818. Pulse receiver 818 may also be formed in semiconductor layer 814 and configured to receive the excitation pulse at the second excitation element 820B after the pulse passes upward on the first excitation element 820A and through semiconductor layer 84, laterally through the metallization layer 812, and downward on the second excitation element 820B and back through semiconductor layer 814.

Power switch circuits are typically subjected to intensive amount of power dissipation during their operative life and may be subjected to repetitive high stress conditions outside the device specification or mission profile. Repetitive heating up and cooling down of power switch circuits can cause a progressive decrease of their reliability (especially repetitive, aggressive temperature jumps and overtemperature spikes, e.g., continuous short circuit operation), potentially bringing a power switch circuit to thermal degradation where the switching functionality is not available any longer. Rather than rely on device failure to prompt circuit or system maintenance, it is desirable to predict problems or circuit failure before it occurs. In some examples, this disclosure describes methods of measurement of lateral parameters of power switch either in a 1-dimensional vector or 2-dimensional matrix to perform “failure anticipation” in the power switch.

Vertical measurements may also be used (e.g., in combination with lateral measurements). Vertical measurements (by themselves) however, may have limited sensitivity to degradation effects in the metallization, because local damages are “bypassed” through the bulk of the metallization that is still not damaged. With vertical measurements alone it may be difficult or impossible to detect degradation in the metallization until such failures are very dominant and the power switch is failing.

The techniques described herein, in some examples, is based on a transfer charge measurement applied laterally to the metallization. A pulse can be injected with a controlled energy pulse which provides a defined amount of charge. On one side, a sensor (e.g., a receiver) is installed to detect the applied pulse after its propagation through the metallization layer. The applied charge passes through the metallization and it is scattered and/or reflected by the inhomogeneities in the metallization. The effect of the inhomogeneities is cumulated through path between injection and detection, therefore with a much higher sensitivity to progressive appearance of degradation effects.

As demonstrated herein, the controlled energy pulse can be applied in one location or in multiple locations (activated either simultaneously or sequentially) and the detection sensors can be applied in one location or in multiple location-depending on the size and geometry of the power switch.

In case multiple locations are used for pulse generation and for detection, the accuracy of the method is improved, and in some cases, a 2-dimensional matrix of excitation locations can be defined as shown in FIG. 4, making it easier and more precise in detecting degradation effects in the metallization in multiple locations.

The procedure of injecting the controlled energy pulse and detection at the sensors (i.e., the injector and the receiver) may be performed at the beginning of the power switch lifetime (“0-hour” status) and then on regular basis (depending on the application requirements) during power switch lifetime, e.g. in defined diagnosis cycles. The results of each injection-detection operation may be compared with the previous results, thereby providing a progressive trend of degradation in the metallization of the power switch. Furthermore, any degradation trend can be compared with a fixed or adjustable threshold, defined either by the power switch user or by the power switch supplier, that anticipates a possible failure in the power switch. The user can decide if the power switch can be operated further (with possibly limited performances) or if the system has to be replaced (“predictive maintenance”) once the power switch reaches a particular level of degradation defined by signal loss (through the metallization layer) in a lateral signal path from the injector to the receiver.

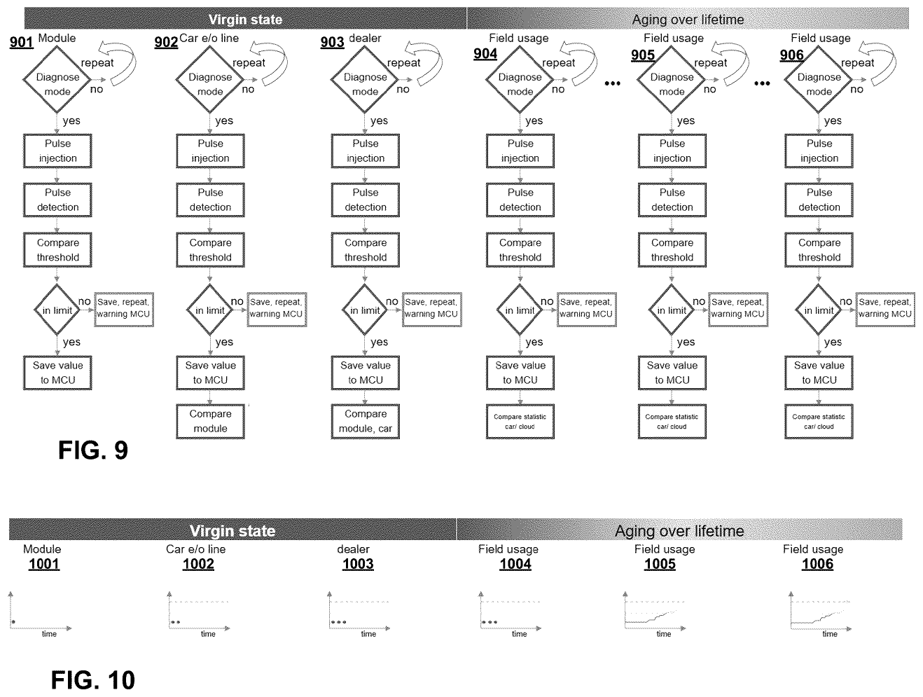

FIG. 9 is a flow diagram showing measurements at different times consistent with this disclosure, and additional fleet-level analysis that may be performed. FIG. 9 demonstrates a cradle to grave approach for checking and monitoring the integrity of a power switch circuit in an automobile. The circuit may be checked in stage 901 when a circuit module is produced or arranged in a production stage. The circuit may be checked again in stage 902 during assembly of the car/automobile. The circuit may be checked again in stage 903 by a dealer, and the circuit may be checked periodically during field usage at stages 904, 905, and 906. In each stage, the circuit may be checked during a diagnosis mode of the automobile or circuit. For electric vehicles, diagnosis mode may correspond to a time when the vehicle is being charged. During a diagnosis mode the checking process can be performed, which may include pulse injection, pulse detection, and a comparison of the detected pulse to a threshold. If the circuit is within its operating parameters associated with the metal layer (yes of “in limit”), then values may be stored by an MCU (e.g., stored in memory 572) shown in FIG. 5. In stage 902, comparisons can be made with other circuit modules. In stage 903, comparisons can be made to other circuit modules or other cars. In stages 904, 905, 906, comparisons can be made to other circuit modules or other cars or fleet-level data in the cloud (e.g., stored on a server associated with the automobile manufacturer, dealer, fleet manager, or other fleet-level entity).

FIG. 10 demonstrates the accumulation of measured data of a circuit device over the life of the device. Graph 1001 corresponds to data in stage 901, graph 1002 corresponds to data accumulated in stages 901 and 902. Graph 1003 corresponds to data accumulated in stages 901-903, graph 1004 corresponds to data accumulated in stages 901-904, and graph 1005 corresponds to data accumulated in stages 901-905. The final graph 1006 corresponds to data accumulated in stages 901-906, and in this case, the data may indicate that the circuit has reached its end-of-life threshold.

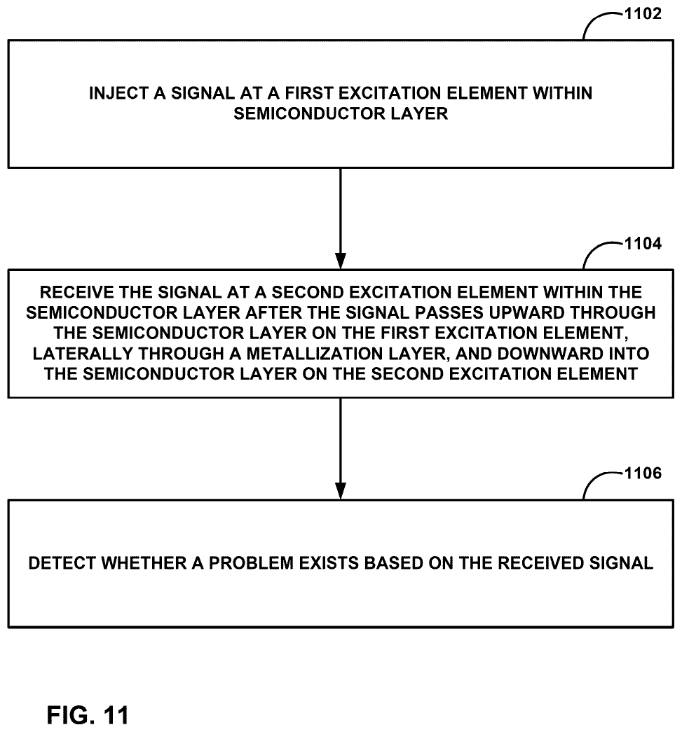

FIG. 11 is an example flow diagram consistent with one or more techniques of this disclosure. FIG. 11 will be described from the perspective of device 60 shown in FIG. 6, although other devices consistent with disclosure may be used to perform the method of FIG. 11. In FIG. 6, injector 662 and receiver 672 are illustrated conceptually, but these elements may be formed in semiconductor layer 614 (e.g., within semiconductor layer 814 above a semiconductor substrate 892 as shown in FIG. 8). Element 690 of FIG. 6 represents logic circuitry, e.g., in a controller (such as an MCU) that may be formed in semiconductor layer 614 or in a controller that is separate from device 60 and external to device 60.

As shown in FIG. 11, a method may include injecting a signal in a circuit device 60 within a semiconductor layer 614 (1102). In this example, the circuit device 60 comprises a semiconductor layer 614 comprising at least a portion of one or more power transistors, and a metallization layer 612 formed over the semiconductor layer 614. A plurality of excitation elements 620A, 620B are formed into the semiconductor layer 614, wherein the excitation elements 620A, 620B extend through the semiconductor layer 614 to the metallization layer 612, wherein injecting the signal occurs into a first excitation element 620A.

The method also includes receiving the signal via a second excitation element 620B (1104), i.e., after the signal passes upward through semiconductor layer 614 on the first excitation element 620A, laterally through the metallization layer 612, and downward through the semiconductor layer 614 on the second excitation element 620B. Logic element 690 may then detect whether an degradation problem exists in circuit device 60 based on the received signal. Lotic element 660, for example may comprise a compare unit 680 configured to compare the received signal to a threshold, wherein detecting whether the degradation problem exists based on the received signal comprises comparing the received signal to the threshold. The threshold may be pre-defined and stored in memory, or in some cases, the threshold may be generated by injector 616 and sent to compare unit 680 such that the sent signal that is generated by injector 616 and the received signal captured by reliever 618 are compared by compare unit 680. In some examples, logic element 690 may be configured to issue an alert (e.g., FAULT 684) in response to determining that the degradation problem exists when the difference between the sent signal and the received signal deviates by a defined amount (“yes” branch of 682). Logic 690 may also be configured to determine that device 60 is OK (e.g., OK 686) in response to determining that problems do not exist in device 60 because a difference between the sent signal and the received signal does not deviate by the defined amount (“no” branch of 682).

In some examples, in response to determining that an degradation problem exists, a controller of device 60 may be configured to at least partially disabling device 60. In other cases, in response to determining that an degradation problem exists, the controller of device 60 may issue an alert (e.g., to a system level controller or unit) that indicates a need to replace device or a need to replace a larger component or module that includes the device.

Consistent with the method shown in FIG. 11, as further illustrated in FIGS. 7A and 7B, in some examples, the method shown in FIG. 11 may further comprise injecting and receiving different signals at a first instance of time (e.g., as shown in FIG. 7A) and a second instance of time (e.g., as shown in FIG. 7B), wherein the circuit device further comprises a selector circuit that includes switches (see e.g., 560 of FIG. 5), wherein the selector circuit is configured to select the first excitation element for the pulse injector and select the second excitation element for the pulse receiver in the first instance of time and configured to select the second excitation element for the pulse injector and select a third excitation element for the pulse receiver in the second instance of time. In other words, excitation element 720B can be used for by receiver 718 in FIG. 7A, which may correspond to the first instance of time, and the same excitation element 720B can be used by injector 716 in FIG. 7B, which may correspond to the second instance of time.

The techniques described in this disclosure may be implemented in circuitry. In various examples, the techniques may be implemented, at least in part, in circuitry, hardware, software, firmware or any combination thereof. For example, various aspects of the described techniques may be implemented within one or more logical elements, processors, including one or more microcontrollers, microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such circuitry, hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components, or integrated within common or separate hardware or software components.

It may also be possible for one or more aspects of this disclosure to be performed in software, in which case those aspects of the techniques described in this disclosure may also be embodied or encoded in a computer-readable medium, such as a computer-readable storage medium, containing instructions. Instructions embedded or encoded in a computer-readable storage medium may cause a processor, to perform the method, e.g., when the instructions are executed. The instructions, in this example, may be stored in a memory, which may comprise random access memory (RAM), read only memory (ROM), programmable read only memory (PROM), erasable programmable read only memory (EPROM), electronically erasable programmable read only memory (EEPROM), flash memory, or other computer readable media.

The following clauses set forth various features consistent with this disclosure.

Clause 1—A device comprising: a semiconductor layer comprising at least a portion of one or more power transistors; a metallization layer formed over the semiconductor layer; and a plurality of excitation elements formed in the semiconductor layer, wherein the excitation elements extend through the semiconductor layer to the metallization layer such that an excitation pulse can be delivered into a first excitation element and received from a second excitation element after passing laterally through the metallization layer.

Clause 2—The device of clause 1, wherein at least some of the plurality of excitation elements are arranged linearly along a major diameter of the device.

Clause 3—The device of clause 1 or 2, wherein at least some of the plurality of excitation elements are arranged in a two-dimensional matrix in the device.

Clause 4—The device of any of clauses 1-3, wherein the plurality of excitation elements are arranged such that each of the excitation elements is equally spaced relative to another of the excitation elements.

Clause 5—The device of any of clauses 1-4, wherein the excitation elements comprise conductor elements that extend through the semiconductor layer to the metallization layer such that an electrical current pulse can be delivered into the first excitation element and received from the second excitation element after passing upward on the first excitation element and through the semiconductor layer, laterally through the metallization layer, and downward on the second excitation element and into the semiconductor layer.

Clause 6—The device of any of clauses 1-5, wherein the device further comprises: a pulse injector formed in the semiconductor layer and configured to generate the excitation pulse and deliver the excitation pulse to the first excitation element and laterally through the metallization layer; and a pulse receiver formed in the semiconductor layer and configured to receive the excitation pulse at the second excitation element after the pulse passes upward on the first excitation element and through the semiconductor layer, laterally through the metallization layer, and downward on the second excitation element and through the semiconductor layer.

Clause 7—The device of clause 6, wherein the device further comprises a compare unit configured to compare the received excitation pulse to a threshold.

Clause 8—The device of clause 7, wherein the device is configured to issue an alert in response to output of the compare unit indicating a potential problem with the device.

Clause 9—The device of clause 8, wherein the alert indicates a potential delamination or cratering problem with the device.

Clause 10—The device of clause 9, wherein the device is at least partially disabled in response to the alert.

Clause 11—The device of clause 9, wherein the alert identifies a need to replace the device or a need to replace a larger component that includes the device.

Clause 12—The device of any of clauses 6-11, further comprising a selector circuit, wherein the selector circuit is configured to select the first excitation element for the pulse injector and select the second excitation element for the pulse receiver in a first instance of time.

Clause 13—The device of clause 12, wherein at a second instance of time, the selector circuit is configured to select the second excitation element for the pulse injector and select a third excitation element for the pulse receiver.

Clause 14-A system comprising: a circuit device comprising: a semiconductor layer comprising at least a portion of one or more power transistors, a metallization layer formed over the semiconductor layer, and a plurality of excitation elements formed into the semiconductor layer, wherein the excitation elements extend through the semiconductor layer to the metallization layer such that an excitation pulse can be delivered into a first excitation element and received from a second excitation element after passing laterally through the metallization layer; and a controller configured to control the circuit device, wherein the controller receives an alert from the circuit device based on the excitation pulse.

Clause 15—The system of clause 14, wherein the circuit device comprises: a pulse injector configured to generate the excitation pulse and deliver the excitation pulse to the first excitation element; a pulse receiver configured to receive the excitation pulse at the second excitation element; a selector circuit that includes switches, wherein the selector circuit is configured to select the first excitation element for the pulse injector and select the second excitation element for the pulse receiver in a first instance of time; and a compare unit configured to compare the received excitation pulse to a threshold and issue the alert in response to the received excitation indicating a potential problem with the device.

Clause 16—The system of clause 15, wherein the controller is further configured to store comparison results of the compare unit over a history associated with the device.

Clause 17—The system of clause 16, wherein the controller is configured to output the comparison results for fleet-level analysis of the device relative to other devices in a fleet.

Clause 18. A method comprising: injecting a signal in a circuit device, wherein the circuit device comprises: a semiconductor layer comprising at least a portion of one or more power transistors; a metallization layer formed over the semiconductor layer; and a plurality of excitation elements formed into the semiconductor layer, wherein the excitation elements extend through the semiconductor layer to the metallization layer, wherein injecting the signal occurs into a first excitation element; receiving the signal via a second excitation element after the signal passes upward through the semiconductor layer on the first excitation element, laterally through the metallization layer, and downward through the semiconductor layer on the second excitation element; and detecting whether an degradation problem exists in the circuit device based on the received signal.

Clause 19—The method of clause 18, wherein the circuit device further comprises a compare unit configured to compare the received signal to a threshold, wherein detecting whether the degradation problem exists based on the received signal comprises comparing the received signal to the threshold.

Clause 20—The method of clause 18 or 19, further comprising issuing an alert in response to determining that the degradation problem exists.

Clause 21—The method of any of clauses 18-20, further comprising at least partially disabling the circuit device in response to determining that the degradation problem exists.

Clause 22—The method of any of clauses 18-21, the method further comprising injecting and receiving different signals at a first instance of time and a second instance of time, wherein the circuit device further comprises a selector circuit that includes switches, wherein the selector circuit is configured to select the first excitation element for the pulse injector and select the second excitation element for the pulse receiver in the first instance of time and configured to select the second excitation element for the pulse injector and select a third excitation element for the pulse receiver in the second instance of time.

Various examples have been described. These and other examples are within the scope of the following claims.

1. A device comprising:
a semiconductor layer comprising at least a portion of one or more power transistors;
a metallization layer formed over the semiconductor layer; and
a plurality of excitation elements formed in the semiconductor layer, wherein the excitation elements extend through the semiconductor layer to the metallization layer such that an excitation pulse can be delivered into a first excitation element and received from a second excitation element after passing laterally through the metallization layer.

2. The device of claim 1, wherein at least some of the plurality of excitation elements are arranged linearly along a major diameter of the device.

3. The device of claim 1, wherein at least some of the plurality of excitation elements are arranged in a two-dimensional matrix in the device.

4. The device of claim 1, wherein the plurality of excitation elements are arranged such that each of the excitation elements is equally spaced relative to another of the excitation elements.

5. The device of claim 1, wherein the excitation elements comprise conductor elements that extend through the semiconductor layer to the metallization layer such that an electrical current pulse can be delivered into the first excitation element and received from the second excitation element after passing upward on the first excitation element and through the semiconductor layer, laterally through the metallization layer, and downward on the second excitation element and into the semiconductor layer.

6. The device of claim 1, wherein the device further comprises:
a pulse injector formed in the semiconductor layer and configured to generate the excitation pulse and deliver the excitation pulse to the first excitation element and laterally through the metallization layer; and
a pulse receiver formed in the semiconductor layer and configured to receive the excitation pulse at the second excitation element after the pulse passes upward on the first excitation element and through the semiconductor layer, laterally through the metallization layer, and downward on the second excitation element and through the semiconductor layer.

7. The device of claim 6, wherein the device further comprises a compare unit configured to compare the received excitation pulse to a threshold.

8. The device of claim 7, wherein the device is configured to issue an alert in response to output of the compare unit indicating a potential problem with the device.

9. The device of claim 8, wherein the alert indicates a potential delamination or cratering problem with the device.

10. The device of claim 9, wherein the device is at least partially disabled in response to the alert.

11. The device of claim 9, wherein the alert identifies a need to replace the device or a need to replace a larger component that includes the device.

12. The device of claim 6, further comprising a selector circuit, wherein the selector circuit is configured to select the first excitation element for the pulse injector and select the second excitation element for the pulse receiver in a first instance of time.

13. The device of claim 12, wherein at a second instance of time, the selector circuit is configured to select the second excitation element for the pulse injector and select a third excitation element for the pulse receiver.

14. A system comprising:
a circuit device comprising:
a semiconductor layer comprising at least a portion of one or more power transistors,
a metallization layer formed over the semiconductor layer, and
a plurality of excitation elements formed into the semiconductor layer, wherein the excitation elements extend through the semiconductor layer to the metallization layer such that an excitation pulse can be delivered into a first excitation element and received from a second excitation element after passing laterally through the metallization layer; and
a controller configured to control the circuit device, wherein the controller receives an alert from the circuit device based on the excitation pulse.

15. The system of claim 14, wherein the circuit device comprises:
a pulse injector configured to generate the excitation pulse and deliver the excitation pulse to the first excitation element;
a pulse receiver configured to receive the excitation pulse at the second excitation element;
a selector circuit that includes switches, wherein the selector circuit is configured to select the first excitation element for the pulse injector and select the second excitation element for the pulse receiver in a first instance of time; and
a compare unit configured to compare the received excitation pulse to a threshold and issue the alert in response to the received excitation indicating a potential problem with the device.

16. The system of claim 15, wherein the controller is further configured to store comparison results of the compare unit over a history associated with the device.

17. The system of claim 16, wherein the controller is configured to output the comparison results for fleet-level analysis of the device relative to other devices in a fleet.

18. A method comprising:
injecting a signal in a circuit device, wherein the circuit device comprises:
a semiconductor layer comprising at least a portion of one or more power transistors;
a metallization layer formed over the semiconductor layer; and
a plurality of excitation elements formed into the semiconductor layer, wherein the excitation elements extend through the semiconductor layer to the metallization layer, wherein injecting the signal occurs into a first excitation element;
receiving the signal via a second excitation element after the signal passes upward through the semiconductor layer on the first excitation element, laterally through the metallization layer, and downward through the semiconductor layer on the second excitation element; and
detecting whether a degradation problem exists in the circuit device based on the received signal.

19. The method of claim 18, wherein the circuit device further comprises a compare unit configured to compare the received signal to a threshold, wherein detecting whether the degradation problem exists based on the received signal comprises comparing the received signal to the threshold.

20. The method of claim 18, further comprising issuing an alert in response to determining that the degradation problem exists.

21. The method of claim 18, further comprising at least partially disabling the circuit device in response to determining that the degradation problem exists.

22. The method of claim 18, the method further comprising injecting and receiving different signals at a first instance of time and a second instance of time, wherein the circuit device further comprises a selector circuit that includes switches, wherein the selector circuit is configured to select the first excitation element for the pulse injector and select the second excitation element for the pulse receiver in the first instance of time and configured to select the second excitation element for the pulse injector and select a third excitation element for the pulse receiver in the second instance of time.
